(19) United States
(12) Patent Application Publication
(10) Pub. No.: US 2015/0068584 A1
(43) Pub. Date: Mar. 12, 2015

(54) PHOTOVOLTAIC SYSTEM WITH MICRO-CONCENTRATOR ARRAY

(71) Applicant: Sandia Corporation, Albuquerque, NM (US)

(72) Inventors: William C. Sweatt, Albuquerque, NM (US); Bradley Howell Jared, Albuquerque, NM (US); Michael P. Saavedra, Albuquerque, NM (US); Benjamin John Anderson, Eden Prairie, MN (US); Ronald S. Goeke, Albuquerque, NM (US); Gregory N. Nielson, Albuquerque, NM (US); Murat Okandan, Edgewood, NM (US); Brenton Elisberg, Albuquerque, NM (US)

(21) Appl. No.: 14/480,268

(22) Filed: Sep. 8, 2014

Related U.S. Application Data
(60) Provisional application No. 61/874,531, filed on Sep. 6, 2013.

(51) Int. Cl. H01L 31/054; H01L 31/0725; H01L 31/0232; G02B 1/04; H01L 31/18; H01L 31/0687; G02B 3/00

(52) U.S. Cl. CPC H01L 31/0543; H01L 31/0687; H01L 31/0725; G02B 3/0068; G02B 1/041; H01L 31/18; H01L 31/02327
USPC 136/246; 359/622; 438/14

(57) ABSTRACT

A photovoltaic system is described herein. The photovoltaic system includes an array of micro-concentrators. Each micro-concentrator includes an exterior lens, an interior lens, and a transparent layer that is between the exterior lens and the interior lens. The array of micro-concentrators is optically aligned with an array of photovoltaic cells.

### RELATED APPLICATION

This application claims priority to U.S. Provisional Patent Application No. 61/874,531, filed on Sep. 6, 2013, and entitled “MICRO-CONCENTRATORS FOR MICROSYSTEMS-ENABLED PHOTOVOLTAICS”, the entirety of which is incorporated herein by reference.

### STATEMENT OF GOVERNMENTAL INTEREST

This invention was developed under Contract DE-AC04-94AL85000 between Sandia Corporation and the U.S. Department of Energy. The U.S. Government has certain rights in this invention.

### BACKGROUND

Conventionally, power plants that burn fossil fuels have been the primary source of electrical energy provided to the electric grid. It has relatively recently become evident, however, that these power plants should be supplemented with energy systems that generate electricity based upon renewable resources, such as sunlight, wind, waves, or the like. Energy systems that generate electricity based upon renewable energy resources exhibit various advantages over the conventional power plant, wherein such advantages include, but are not limited to, fewer pollutants emitted into the environment and conservation of finite natural resources (such as coal and oil).

With reference to solar systems, such systems include a plurality of solar cells that are configured to convert solar radiation to harvestable electrical energy. Relatively recently, it has been ascertained that particular types of solar cells are fairly efficient in converting solar radiation to electrical energy. For example, III-V cells have been observed to convert solar radiation to electrical energy at relatively high efficiencies. Materials used in these cells, however, tends to be somewhat expensive, particularly when compared to conventional silicon cells. Accordingly, to reduce expense, it is desirable to maximize the electrical energy that can be generated by such cells.

An exemplary mechanism that has been implemented to increase the amount of energy that can be generated by an array of photovoltaic cells is a tracking mechanism. For example, a photovoltaic system, which includes an array of solar cells, can be mounted on a relatively stable structure, and the tracking mechanism moves the structure such that the structure tracks the sun as the sun moves across the sky. These tracking mechanisms, however, are costly themselves. Accordingly, it is desirable for relative coarse tracking mechanisms to be employable, and is further desirable for the solar system to be relatively lightweight.

### SUMMARY

The following is a brief summary of subject matter that is described in greater detail herein. This summary is not intended to be limiting as to the scope of the claims.

Described herein are various technologies relating to a photovoltaic system. With more particularity, described herein are various technologies relating to a photovoltaic system that includes an array of micro-concentrators, wherein the array of micro-concentrators are configured to direct concentrated beams of solar radiation to an array of photovoltaic cells placed in close proximity thereto. The array of micro-concentrators includes a plurality of micro concentrators that are respectively optically aligned with a plurality of photovoltaic cells in the array of photovoltaic cells. The incorporation of the array of micro-concentrators into the photovoltaic system allows for less material (e.g., III-V material) to be utilized when constructing the stacked photovoltaic array, which in turn results in decreased expense compared to conventional photovoltaic systems.

The array of micro-concentrators includes a first lens array that comprises first lenses and a second lens array that comprises second lenses, wherein the first lenses are respectively optically aligned with the second lenses. In an example, the first lenses and the second lenses can be formed of a polycarbonate. The array of micro-concentrators also includes a transparent layer that is positioned between the first lens array and the second lens array. Inclusion of the transparent layer causes the array of micro-concentrators to be free of an air gap between the first lens array and the second lens array. In an exemplary embodiment, the transparent layer can be formed of a plastic, such as polydimethylsiloxane (PDMS), although other silicone-based materials or low-index plastics are also contemplated.

As noted above, the array of micro-concentrators is free of an air gap between the first lens array and the second lens array (as the gap between the first lens array and the second lens array is populated by the transparent layer). Accordingly, when the array of micro-concentrators is subjected to temperature variations, air is unable to pass between the first lenses in the first lens array and the second lenses in the second lens array, and thus, dust, water vapor, and other contaminants are not introduced between the first lenses and the second lenses of the micro-optical concentrator array.

The above summary presents a simplified summary in order to provide a basic understanding of some aspects of the systems and/or methods discussed herein. This summary is not an extensive overview of the systems and/or methods discussed herein. It is not intended to identify key/critical elements or to delineate the scope of such systems and/or methods. Its sole purpose is to present some concepts in a simplified form as a prelude to the more detailed description that is presented later.

### BRIEF DESCRIPTION OF THE DRAWINGS

FIG. 1 illustrates a portion of an exemplary photovoltaic system.

FIG. 2 is a cross-sectional view of an exemplary photovoltaic system that comprises an array of micro-concentrators.

FIG. 3 is an isometric view of an exemplary array of lenses.

FIG. 4 illustrates an exemplary micro- concentrator that is configured to direct a concentrated beam of light towards a photovoltaic cell.

FIG. 5 is a block diagram of an exemplary photovoltaic system that is configured to track movement of the sun.

FIG. 6 is a flow diagram illustrating an exemplary methodology for forming a photovoltaic system.

FIG. 7 is a flow diagram that illustrates an exemplary methodology for forming an array of micro-concentrators.

### DETAILED DESCRIPTION

Various technologies pertaining to photovoltaic systems are now described with reference to the drawings, wherein like reference numerals are used to refer to like elements throughout. In the following description, for purposes of explanation, numerous specific details are set forth in order to provide a thorough understanding of one or more aspects. It may be evident, however, that such aspect(s) may be practiced without these specific details. In other instances, well-known structures and devices are shown in block diagram form in order to facilitate describing one or more aspects. Further, it is to be understood that functionality that is described as being carried out by certain system components may be performed by multiple components. Similarly, for instance, a component may be configured to perform functionality that is described as being carried out by multiple components.

Moreover, the term “or” is intended to mean an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form. Further, as used herein, the term “exemplary” is intended to mean serving as an illustration or example of something, and is not intended to indicate a preference. Additionally, the term “about” is intended to encompass a stated value characterized by the term “about” and values within 10% of the stated value.

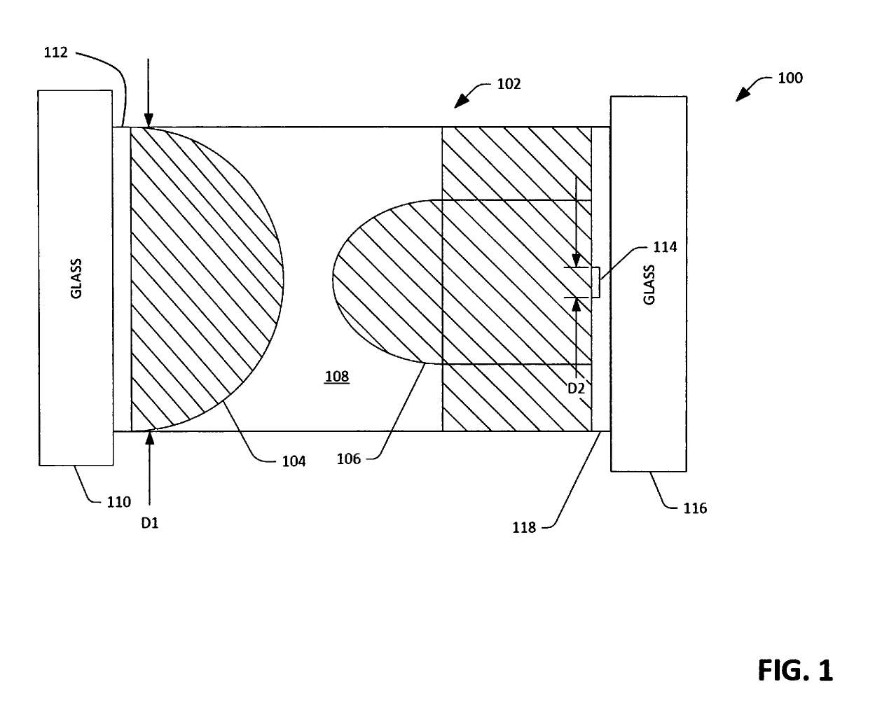

With reference now to FIG. 1, a cross-sectional diagram of a portion of an exemplary photovoltaic system 100 is illustrated. The portion of the photovoltaic system 100 includes a micro-concentrator 102. The micro-concentrator 102 includes a first lens 104 and a second lens 106, wherein the second lens 106 is positioned in optical alignment with the first lens 104. The micro-concentrator 102 additionally includes a transparent layer 108 that is formed of a transparent material, wherein the transparent layer 108 is positioned between the first lens 104 and the second lens 106. As can be ascertained, an entry aperture of the first lens 104 has a first diameter D1, while an exit aperture of the second lens 106 has a second diameter D2, wherein D1 is greater than D2. In an example, D1 can be between 5×D2 and 14×D2 giving an area magnification between 25 and 225. In a particular example, D1 can be approximately 10×D2. In an example, the apertures of the first lens 104 and/or the second lens 106 may be circular, although the lenses are not so limited. For instance, the apertures may be hexagonal, square, octagonal, etc.

Further, the first lens 104 and the second lens 106 may be formed of a material having a relatively high index of refraction. For instance, such material may be a thermoplastic polymer. In a particular example, the material may be polycarbonate. The first lens 104 and/or the second lens 106 may be formed of a material that has an index of refraction between about 1.5 and about 1.8. Polycarbonate, for instance, has an index of refraction of n=1.59. It is also possible to form the first and second lens arrays from a silicone like polydimethylsiloxane (PDMS) that is filled with high-index nanoparticles. The nanoparticles can be made of zirconia (ZrO₂), titania (TiO₂), diamond, or the like. The volume fill can be between 10% and 50%. The transparent layer 108 may be formed of a silicone-based material, such as PDMS. For instance, PDMS has an index of refraction of n=1.40. It can be ascertained that the index of refraction of the material of which the lenses 104 and 106 are formed can be greater than the index of refraction of the material of which the transparent layer 108 is formed, wherein a relatively large difference between such indices of refraction is desired.

The portion of the photovoltaic system 100 can also include a first glass plate 110 that is positioned adjacent to the first lens 104. The first glass plate 110 can have an anti-reflective (AR) coating applied thereto. The system 100 also includes a first adhesive layer 112 formed of a transparent optical adhesive that is configured to cause the glass 110 to adhere to the first lens 104 of the micro-concentrator 102. For example, the optical adhesive can be formed of a urethane adhesive. The glass plate 110 acts as a protective layer for the micro-concentrator 102 and other elements in the portion of the photovoltaic system.

The system 100 further comprises a photovoltaic cell 114, which is placed adjacent to the second lens 106 of the micro-concentrator 102. In an example, the photovoltaic cell 114 can be a relatively small photovoltaic cell, such as one with a diameter of approximately 0.25 mm. In an example, the photovoltaic cell 114 can be manufactured by way of semiconductor manufacturing techniques, thus enabling the photovoltaic cell to be manufactured at micro-scale. In a non-limiting example, the photovoltaic cell 114 may be or include a stack of photovoltaic cells including III-V cells, such that stack can include, for example, a gallium arsenide (GaAs) cell, an indium gallium arsenide (InGaAs) cell, a silicon cell, an indium gallium phosphate (InGaP) cell, amongst others. In another example, the photovoltaic cell 114 may be a multi junction cell formed of several different photovoltaic cells, such as those referenced above. Further, the photovoltaic cell 114 may be grown on a base substrate, such as a silicon substrate. The photovoltaic cell may also be comprised of a single junction silicon cell.

The photovoltaic system 100 may also include a second adhesive layer (not shown) that is configured to cause the second lens 106 to adhere to the photovoltaic cell 114. For example, the second adhesive layer may be formed of a transparent adhesive that has an index of refraction that is approximately equal to the index of refraction of the material of the second lens 106. The system 100 further includes a second glass plate 116 that is placed adjacent to the substrate upon which the photovoltaic cell 114 is grown (or adjacent to a protective backplane that is adhered to the back side of the photovoltaic cell 114). The system 100 includes a third adhesive layer 118 that is configured to cause the substrate or backplane to adhere to the second glass plate 116.

Operation of the portion of the photovoltaic system 100 will now be described. The portion of the photovoltaic system 100 can be positioned such that solar radiation is incident on the first glass plate 110. The solar radiation can pass through the first glass plate 110 and the first adhesive layer 112 to the entry aperture of the first lens 104. The first lens 104 is shaped to direct solar radiation received at the first lens 104 to a focal region behind the second lens 106. In an example, the first lens 104 can be shaped to have a field of view of between about +/−1° and +/−5°. Accordingly, the first lens 104 can direct light to the above-mentioned focal region, even if such light does not travel parallel to an optical axis of the first lens 104. The light exits an entry aperture of the first lens 104, travels through the transparent layer 108, and enters an entry aperture of the second lens 106. Due to the discrepancy in the indices of refraction between the lenses 104 and 106 and the transparent layer 108, the curvature of the first lens 104 and the second lens 106 need not be drastic. The light is directed by the second lens 106 to the surface of the photovoltaic cell 114. The photovoltaic cell 114 converts the light to electrical energy, and outputs such energy by way of conventional contacting techniques. In an exemplary embodiment, the micro-concentrator can achieve 100× area magnification and greater than 90% optical transmission across a pass band of roughly 400-1600 nm when the micro concentrator is pointed to within an angular error of ±2.5° of the sun. Accordingly, in an example, the diameter of the entry aperture of the first lens 104 D1 can be 2.5 mm, while the diameter of the exit aperture of the second lens 106 can be 0.25 mm.

While FIG. 1 illustrates a portion of a photovoltaic system, it is to be understood that the entirety of the photovoltaic system may include an array of micro-concentrators and a corresponding array of photovoltaic cells, such that there is a 1:1 correspondence of micro-concentrators to photovoltaic cells. Each photovoltaic cell would, thus, be in optical alignment with a respective micro-concentrator in the array of micro-concentrators.

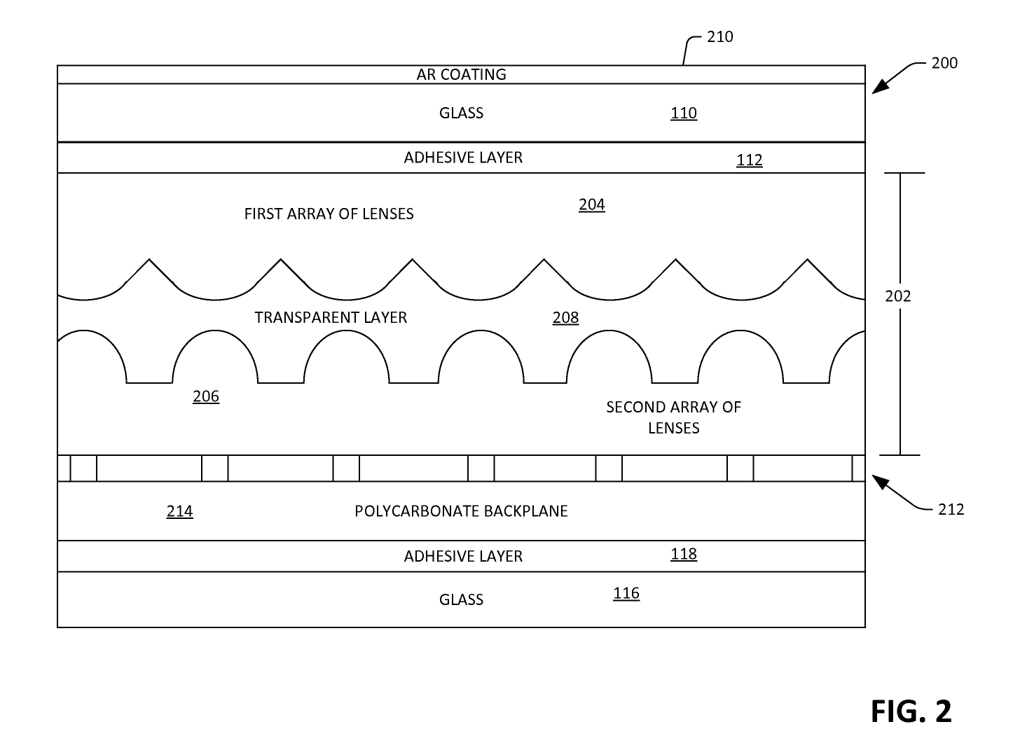

FIG. 2 illustrates a cross-sectional view of an exemplary photovoltaic system 200. The photovoltaic system 200 includes an array of micro-concentrators 202. The array of micro-concentrators 202 includes a first array of lenses 204 (which include a first plurality of lenses such as the first lens 104 shown in FIG. 1), and a second array of lenses 206 (which includes a second plurality of lenses such as the second lens 106 shown in FIG. 1). The first plurality of lenses in the first array of lenses 204 are respectively in optical alignment with the second plurality of lenses in the second array of lenses 206. The micro-concentrator array 202 also includes a transparent layer 208 that is positioned between the first array of lenses 204 and the second array of lenses 206. The first glass plate 110 is adhered to the first lens array 204 by way of the first adhesive layer 112. As described above, an AR coating 210 can optionally be applied to the surface of the first glass plate 110.

The photovoltaic system 200 also includes an array of stacked photovoltaic cells 212. As indicated previously, the stack of photovoltaic cells 212 can include silicon and III-V cells. Further, the array of photovoltaic cells 212 can include multi junction cells. The photovoltaic cell stack can also be comprised by single junction cells. The array of photovoltaic cells 212 is adhered to the second lens array 206 by way of the second adhesive layer referenced above.

The photovoltaic system 200 may also include a polycarbonate or glass backplane 214 upon which the array of photovoltaic cells 212 are adhered. The second glass plate 116 is adhered to the polycarbonate backplane 214 by way of the third adhesive layer 118.

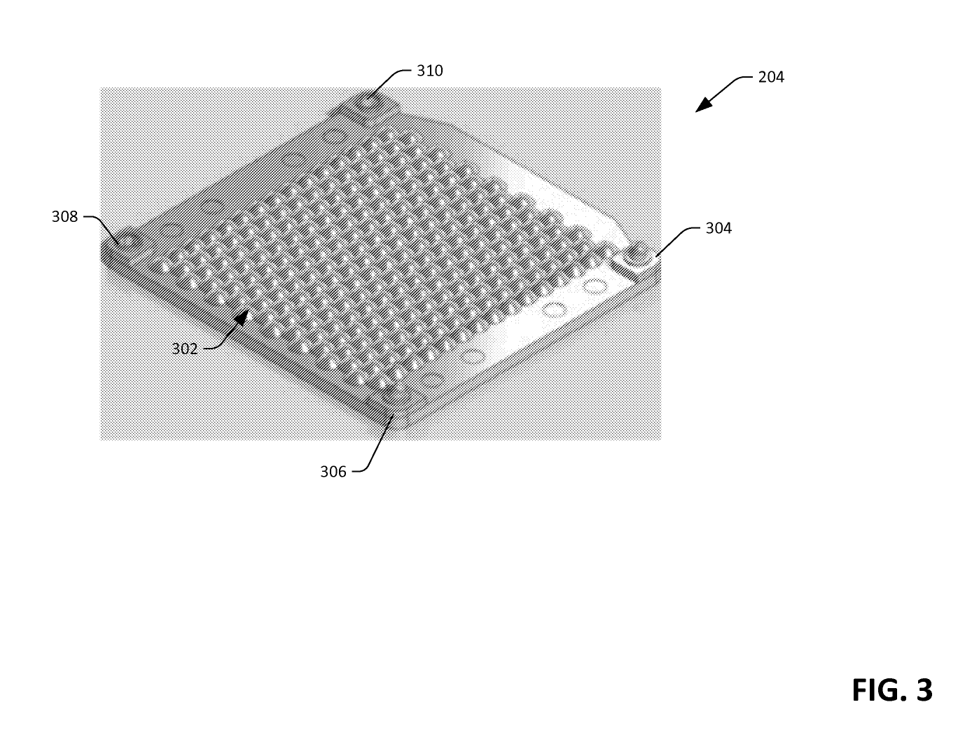

Now referring to FIG. 3, an isometric view of the first array of lenses 204 is illustrated. As can be ascertained, the first array of lenses 204 includes a plurality of lenses 302. The second array of lenses 206 thus includes a corresponding second plurality of lenses that are respectively optically aligned with the plurality of lenses 302 in the first array of lenses 204. The exemplary first array of lenses 204 additionally includes a plurality of alignment mechanisms 304-310. The second array of lenses 206 and/or the array of photovoltaic cells 212 will include corresponding alignment mechanisms, thereby allowing for relatively efficient alignment of the first array of lenses 204 with the second lens array 206, and/or the array of micro-concentrators with the array of photovoltaic cells 212.

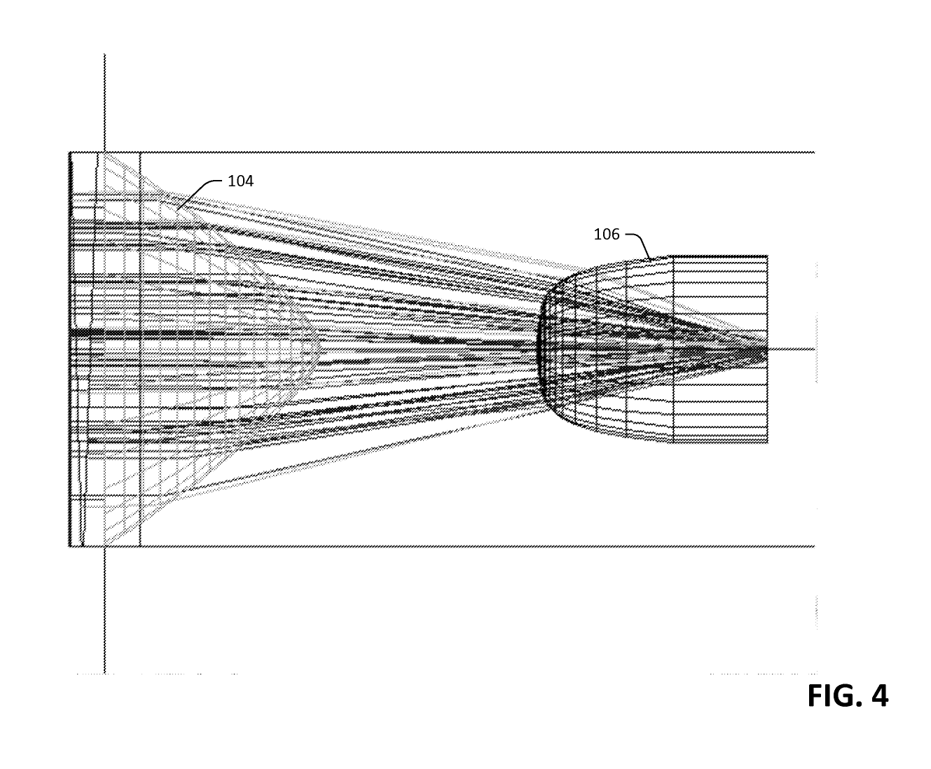

FIG. 4 illustrates light traveling between the first lens 104 and the second lens 106 and through the second lens to the stacked PV cells. Specifically, FIG. 4 illustrates an exemplary optical design and ray tracing for a two plano-convex lens, 8^{th} order aspheric design with 100× area magnification and +/−2.5° field of view. It can be ascertained that magnification can be altered by changing the curvature or aspheric shape of one or both of the lenses 104 and 106, material used to form the lenses 104 and/or 106, material used to form the transparent layer 108, etc.

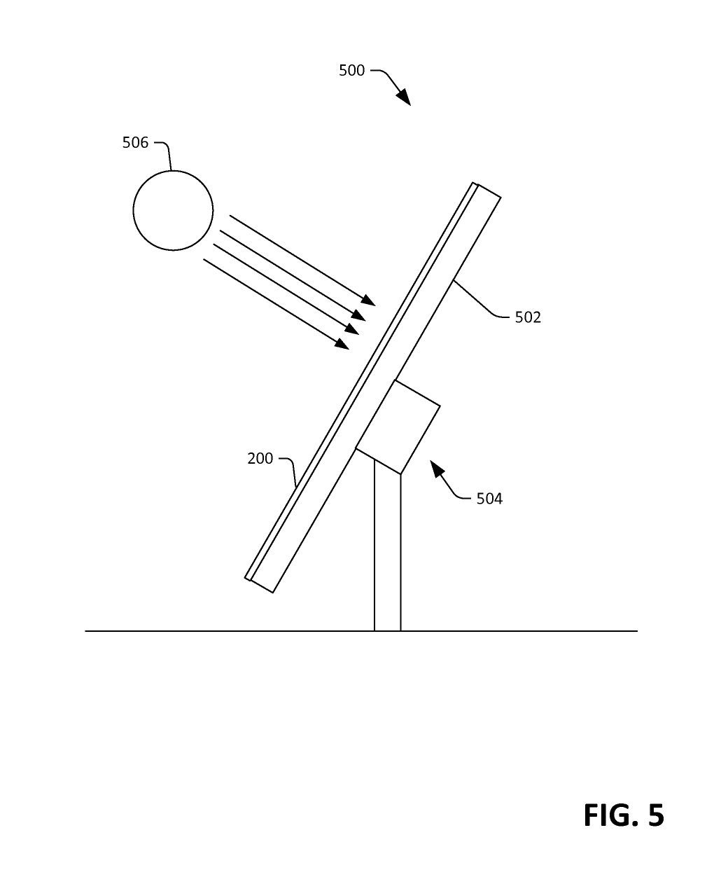

Turning now to FIG. 5, an exemplary photovoltaic system 500 is illustrated. The photovoltaic system 500 includes a mount 502 upon which the photovoltaic system 200 can be mounted. The system 500 also includes a tracking mechanism 504 that is coupled to the mount 502, wherein the tracking mechanism 504 is configured to cause the mount 502, and thus the photovoltaic system 200, to track movement of the sun 506 over time. Due to the medium-sized (e.g. >1°) field of view of the micro-concentrators, the tracking mechanism 504 may be a relatively coarse tracker, thus reducing system cost.

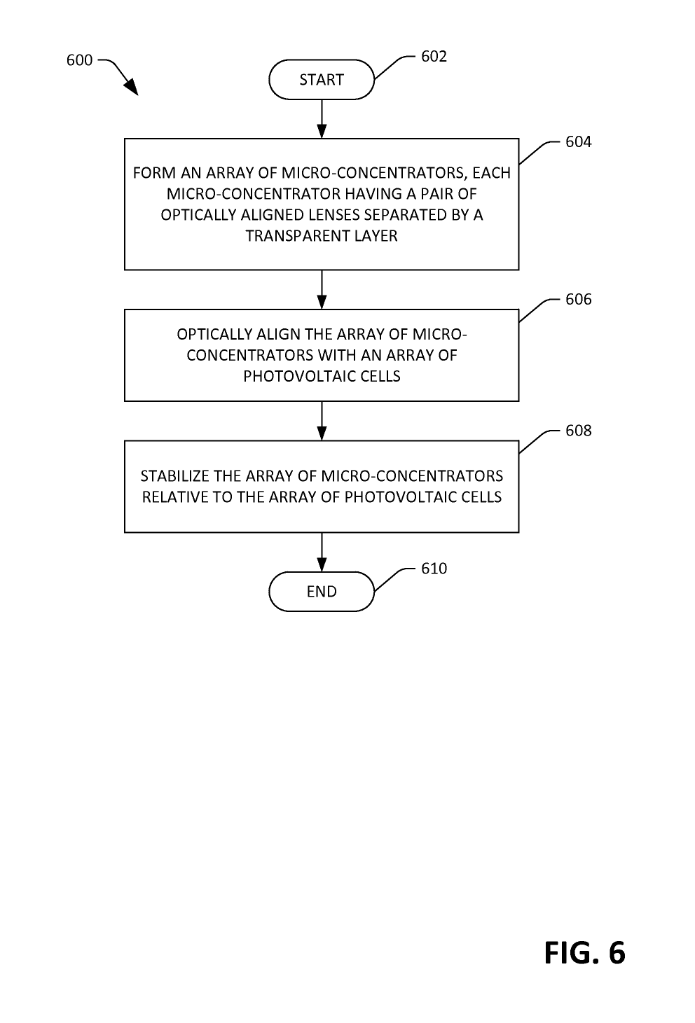

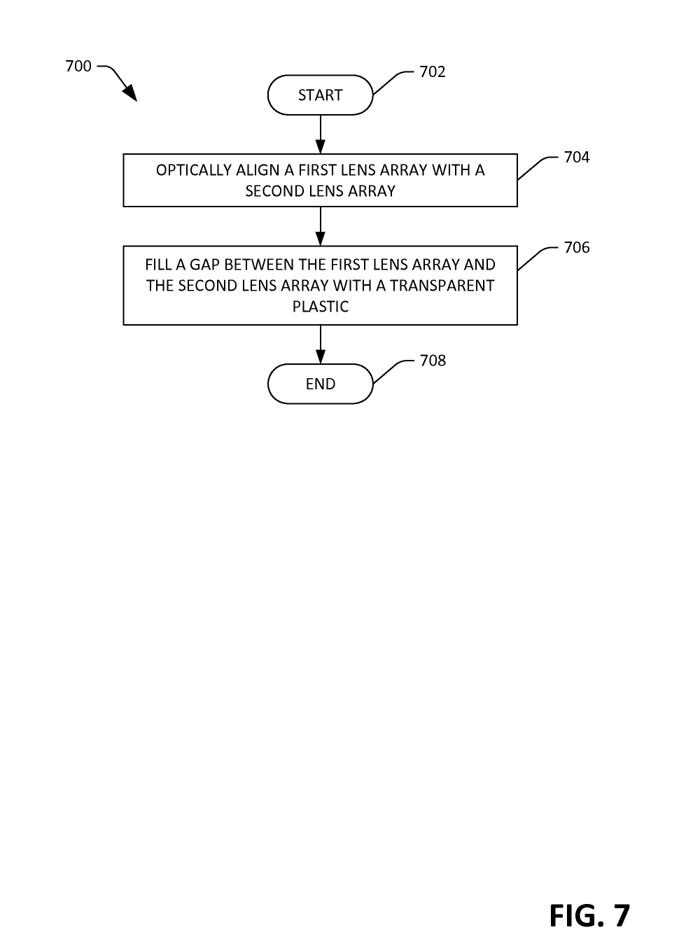

FIGS. 6-7 illustrate exemplary methodologies relating to forming a photovoltaic system. While the methodologies are shown and described as being a series of acts that are performed in a sequence, it is to be understood and appreciated that the methodologies are not limited by the order of the sequence. For example, some acts can occur in a different order than what is described herein. In addition, an act can occur concurrently with another act. Further, in some instances, not all acts may be required to implement a methodology described herein.

Turning to FIG. 6, an exemplary methodology 600 for forming a photovoltaic system is illustrated. The methodology 600 starts at 602, and at 604, an array of micro- concentrators is formed. As described previously, each micro-concentrator in the array of micro-concentrators comprises a pair of optically aligned lenses separated by a transparent layer (e.g., formed of a transparent plastic).

At 606, the array of micro-concentrators is optically aligned with an array of photovoltaic cells. Accordingly, each micro-concentrator in the array of micro-concentrators is optically aligned with a respective photovoltaic cell in the array of photovoltaic cells.

At 608, the array of micro-concentrators is stabilized relative to the array of photovoltaic cells. For example, an adhesive can be applied to at least one of the array of micro-concentrators or photovoltaic cells in the array of photovoltaic cells, such that the array of photovoltaic cells adheres to the array of micro-concentrators. In such a case, the adhesive can have an index of refraction that is approximately equal to the index of refraction of lenses in the micro-concentrators. In another example, the array of photovoltaic cells can be mechanically aligned and fixed to the relative to the array of micro-concentrators (e.g., through fasteners positioned around a periphery of the array of micro-concentrators and/or the array of photovoltaic cells). The methodology 600 completes at 610.

With reference now to FIG. 7, an exemplary methodology 700 that facilitates forming an array of micro-concentrators is illustrated. The methodology 700 starts at 702, and at 704, a first lens array is optically aligned with a second lens array. This alignment can be performed by any suitable techniques, including alignment mechanisms that are positioned on the first lens array and the second lens array, mounting devices utilized to align the first lens array with the second lens array, etc. At 706, a gap between the first lens array and the second lens array is filled with a transparent plastic, such as PDMS. The methodology completes at 708.

### EXAMPLES

The example set forth below are for purpose of illustration and are not intended to be limiting as to the scope of claims.

### Example 1

### Photovoltaic System

A photovoltaic system was designed that included an array of micro-concentrators. The micro-concentrating optics were designed to achieve 100× magnification and greater than 90% optical transmission across a pass band of approximately 400-1600 nm. A +/−2.5° field of view was selected to ensure compatibility with commercial coarse sun tracking systems. Environmental considerations for the optics and module design included a 20-year service life, operating ambient temperatures from between −40° C. to 80° C., and exposure to hail, rain, humidity, dust, and ultraviolet (UV) radiation. Although the design introduced a hot spot with a peak intensity exceeding 700 suns at a surface of a photovoltaic cell, the short thermal conduction path for sub-millimeter-sized photovoltaic cells ensures temperature increases of only a few degrees and minimal degradation in cell performance. Incident rays onto the photovoltaic cell were constrained to less than 30° as the front optic entrance aperture was 2.5 mm with an exit aperture onto the photovoltaic cell of 0.25 mm.

The thickness of the lens “sandwich” (e.g., the first array of lenses 204, the transparent layer 208, and the second array of lenses 206) was approximately 5.30 mm, which is a relatively large reduction from traditional concentrator systems. The optics were arranged to make 240 element hexagonal closed packed array across a roughly 40 mm square collection area using a 15×16 format with 2.381 mm and 2.058 mm pitch spacing, respectively. The error budget for the optical optic surfaces included a +/−5 μm tolerance for form accuracy, a 30 nm Rₐ tolerance for surface finish, a +/−25 μm tolerance for optic to cell planar alignment, and a +/−50 μm tolerance for optic to cell axial placement.

Polycarbonate was selected as the high index (n=1.59) concentrator lens material, due to its low cost and availability for mass production molding. The gap between the two lenses was filled with PDMS (n=1.40) to prevent moisture integration into the concentrator module, to minimize Fresnel reflections, and to ensure high optical transmission without UV degradation. The relatively low elastic modulus of PDMS (2.3 MPa) provides a further advantage in accommodating stresses generated by thermal excursions and CTE mismatches in the optical assembly. Spacing between the front and rear lens array was selected to accommodate stress loads that would be incurred by the micro-concentrator array.

The lens and photovoltaic cell arrays were assembled between two glass plates using a urethane adhesive for an overall module thickness of approximately 9.96 mm. Isolation from environmental contamination was achieved from a butyl sealant around the outside perimeter of the module. Assembly and alignment of the front and rear optic arrays was achieved using asymmetric over-constrained 45° angle pin-in-slot features that were molded into each part. Bosses on the pin feature set the axial position of the two lens elements to one another. The symmetric geometry of the mating features provided an athermal mounting configuration with expected alignment tolerances better than 25 μm. Alignment and assembly of the cell array was also performed passively using monolithic “wedding cake” features on the rear optic array that mate to holes in the polyimide flex. Anti-reflective coatings were included on the front face of the top glass in the photovoltaic cell stack, reducing the air to glass reflective loss from 4% to 1%, and the urethane to GaAs cell reflective loss from 20% to 2%. No coatings were used at the polycarbonate to PDMS interfaces since their losses are on the order of only 0.4% per interface.

### Example 2

### Micro-Concentrator Fabrication

An exemplary fabrication of the optics is now described. The polycarbonate lens arrays were injection molded using aluminum mold inserts that were machined using micro-milling for rough figuring and ultra-precision diamond milling for final finishing. Process development focused on reducing optic surface finish to improve system efficiency, thereby increasing process throughput to reduce manufacturing costs and further reducing diamond tool wear to minimize performance variations across the lens arrays. The front lens element had the minimum surface radius 0.677 mm and maximum lens sag 1.04 mm, while the rear lens element had the highest surface slope (89.2°). Constraints implicit from both machining and molding processes were incorporated into the opto-mechanical design process. Rough micro-milling of the insert produced a surface with approximately 20 μm of remaining stock material and a form error of +/−5 μm. It also significantly reduced the overall machining time and diamond tool wear compared to diamond machining the entire insert surface. The insert was then mounted and aligned into a four-axis diamond turning machine, where a single final finishing pass was performed using diamond milling. Final finishing involved the use of a single diamond tool with a 20 μm nominal radius and a 70° nominal side clearance angle for each mold insert. A form accuracy of 1.5 μm and apex surface finish of 30 nm Rₐ was achieved on a test optic array. Subsequent fabrication of the mold insert for the “wedding cake” features on the rear optic has demonstrated feature dimension accuracies of +/−1-6 μm with positional accuracies of +/−8 μm.

Initial molding experience demonstrated the in-plane material shrinkage across the array was less than 0.2%, as optic centers were located in X and Y with an accuracy of +/−5 μm. Surface finish on the final molded optic arrays was on the order of 25 nm Rₐ.

### Example 3

### Micro-Concentrator Performance

Test samples were assembled comprising front and rear lens arrays bonded together using a PDMS filler without the cover glass, cell array, or AR coatings. Under one sun simulated illumination from a white light source with a 0.5° divergence angle, spot diagrams were generated by re-imaging the output plane corresponding to the location of cells in a complete photovoltaic cell assembly onto a camera detector. The beam profile for on-axis illumination demonstrated good agreement with ray trace simulations under the AM1.5G spectrum from 400 to 2000 nm. Total transmitted optical power emerging from the rear surface of the optical subassembly into air has been measured in a spectral photometer across a spectrum from 400 to 2000 nm. The maximum simulated transmission through the subassembly is 84% due to Fresnel and absorption losses, which agrees well with the data. It should be noted the detected optics have an estimated 5% Fresnel loss at their output from the polycarbonate room lens array into air. This loss will be essentially eliminated in photovoltaic systems using an index matched adhesive between the rear optic array and the cells. Therefore, it is reasonable to expect system transmission levels approaching 90%.

What has been described above includes examples of one or more embodiments. It is, of course, not possible to describe every conceivable modification and alteration of the above devices or methodologies for purposes of describing the aforementioned aspects, but one of ordinary skill in the art can recognize that many further modifications and permutations of various aspects are possible. Accordingly, the described aspects are intended to embrace all such alterations, modifications, and variations that fall within the spirit and scope of the appended claims. Furthermore, to the extent that the term “includes” is used in either the details description or the claims, such term is intended to be inclusive in a manner similar to the term “comprising” as “comprising” is interpreted when employed as a transitional word in a claim.

What is claimed is:

1. A photovoltaic system, comprising:
an array of micro-concentrators, comprising:
a first lens array that comprises a first plurality of lenses;
a second lens array that comprises a second plurality of lenses, the second plurality of lenses respectively positioned in optical alignment with the first plurality of lenses; and
a transparent layer formed of a plastic positioned between the first lens array and the second lens array.

2. The photovoltaic system of claim 1, wherein each lens in the first lens array has an entry aperture with a first diameter, and wherein each lens in the second lens array has an exit aperture with a second diameter, the first diameter greater than the second diameter.

3. The photovoltaic system of claim 2, the first diameter being between 1 mm and 10 mm, the second diameter being between 0.1 mm and 2 mm.

4. The photovoltaic system of claim 1, the first plurality of lenses and the second plurality of lenses being formed of polycarbonate or a material composed of an optical silicone filled with high-index nanoparticles.

5. The photovoltaic system of claim 1, the transparent layer formed of polydimethylsiloxane.

6. The photovoltaic system of claim 1, further comprising:
a first adhesive layer that is positioned between the second lens array and an array of stacked photovoltaic cells, wherein the first adhesive layer is formed of a material having an index of refraction that is approximately equal to an index of refraction of a material of which the second plurality of lenses is formed.

7. The photovoltaic system of claim 6, the array of stacked photovoltaic cells comprises multi junction cells.

8. The photovoltaic system of claim 1, further comprising a first glass layer positioned relative to the first lens array such that the first lens array is between the first glass layer and the transparent layer.

9. The photovoltaic system of claim 8, further comprising a second glass layer positioned relative to the second lens array such that the second lens array is between the second glass layer and the transparent layer.

10. The photovoltaic system of claim 1, further comprising an array of stacked photovoltaic cells, the array of stacked photovoltaic cells comprising a plurality of photovoltaic cells that is respectively positioned in optical alignment with the first plurality of lenses and the second plurality of lenses in the array of micro-concentrators.

11. The photovoltaic system of claim 10, the photovoltaic cells comprising a stack of cells made of silicon and III-V materials.

12. A method for forming a photovoltaic system, the method comprising:
forming an array of micro-concentrators, wherein forming the array comprises:
optically aligning a first lens array with a second lens array such that first lenses in the first lens array are respectively in optical alignment with second lenses in the second lens array;
filling a gap between the first lens array and the second lens array with a transparent plastic material, wherein light that impacts a first lens in the first lenses is directed through the transparent plastic material to a second lens in the second lenses.

13. The method of claim 12, further comprising:
adhering a protective glass layer to the first lens array.

14. The method of claim 12, wherein forming the array of micro-optical concentrators further comprises:
forming the first lenses of the first lens array of a material that has a first index of refraction, wherein the transparent plastic material has a second index of refraction, the first index of refraction being greater than the second index of refraction.

15. The method of claim 14, wherein forming the array of micro-optical concentrators further comprises:
forming the second lenses of the second lens array of the material that has the first index of refraction.

16. The method of claim 15, wherein forming the first lenses comprises forming the first lenses of polycarbonate, and wherein forming the second lenses comprises forming the second lenses of polycarbonate.

17. The method of claim 15, wherein forming the first lenses comprises forming each lens in the first lenses with an entry aperture of a first diameter, wherein forming the second lenses comprises forming each lens in the second lenses with an exit aperture of second diameter, wherein the first diameter is about 10× the second aperture.

18. The method of claim 12, further comprising:
aligning an array of stacked photovoltaic cells with the array of micro-concentrators such that photovoltaic cells in the array of stacked photovoltaic cells are respectively optically aligned with the second lenses in the second lens array; and
responsive to aligning the array of photovoltaic cells with the array of micro-concentrators, stabilizing the array of photovoltaic cells relative to the array of micro-optical concentrators.

19. The method of claim 18, further comprising:
responsive to stabilizing the array of photovoltaic cells relative to the array of micro-concentrators, stabilizing the array of photovoltaic cells and the array of micro-concentrators relative to a tracking structure that is configured to track movement of the sun over time.

20. A photovoltaic system, comprising:
an array of stacked photovoltaic cells, the array of stacked photovoltaic cells comprises a plurality of silicon and III-V photovoltaic cells;
an array of micro-concentrators positioned in optical alignment with the array of stacked photovoltaic cells, wherein micro-concentrators in the array of micro-concentrators are optically aligned with respective photovoltaic cells in the array of stacked photovoltaic cells, each micro-concentrator in the array of micro-concentrators comprises:
an exterior lens that has an entry aperture with a first diameter, the exterior lens formed of polycarbonate;
an interior lens that has an exit aperture of a second diameter, the second diameter being less than the first diameter, the interior lens formed of polycarbonate; and
a transparent layer that is between the exterior lens and the interior lens, the transparent layer formed of polydimethylsiloxane.
